(19) United States
(12) Patent Application Publication
(10) Pub. No.: US 2025/0151587 A1
(43) Pub. Date: May 8, 2025

(54) Display Device

(71) Applicant: LG Display Co., Ltd., Seoul (KR)

(72) Inventors: Yooji Hwang, Paju-si (KR); Yongmin Kim, Paju-si (KR); ByungJoo Lee, Paju-si (KR); JooBong Hyun, Paju-si (KR); Keongjin Lee, Paju-si (KR)

(21) Appl. No.: 18/922,039

(22) Filed: Oct. 21, 2024

(30) Foreign Application Priority Data
Nov. 3, 2023 (KR) 10-2023-0150757

(51) Int. Cl. H10K 59/80; B60K 35/22; H10K 59/122; H10K 59/124; H10K 59/38; H10K 59/40

(52) U.S. Cl. CPC H10K 59/879; B60K 35/22; H10K 59/122; H10K 59/124; H10K 59/38; H10K 59/40; H10K 59/873; H10K 59/8792

(57) ABSTRACT

A display device is disclosed that includes an insulating layer located on a substrate. The insulating layer includes a plurality of concave portions which are located in a plurality of subpixels. An area of a first concave portion disposed in a first subpixel among the plurality of subpixels is larger than an area of a second concave portion disposed in a second subpixel among the plurality of subpixels. A plurality of lens parts are located on the insulating layer, and include a first lens part corresponding to the first concave portion and a second lens part corresponding to the second concave portion. It is possible to provide a display device capable of improving light extraction efficiency.

### CROSS-REFERENCE TO RELATED APPLICATION

This application claims priority from Republic of Korea Patent Application No. 10-2023-0150757 filed on Nov. 3, 2023, which is hereby incorporated by reference in its entirety.

### BACKGROUND

### Field

Embodiments of the present disclosure relate to a display device.

### Description of Related Art

As the information society develops, demands for display devices for displaying an image are increasing in various forms. Recently, various display devices such as a liquid crystal display device, a plasma display device and an organic light emitting display device have been used.

A display device which displays various information on a screen is a core technology in the era of information and communication technology, and plays the role of displaying various information in a display area.

In the display device, excellent display quality and luminous efficiency may be required.

In particular, luminous efficiency is becoming increasingly important as the display device is required to use limited power as technology advances.

The light efficiency of the display device may be determined by a light emitting element included in the display device.

A display device including a light emitting element with excellent light efficiency may have excellent light efficiency.

Therefore, improving the light efficiency of a light emitting element may be considered as a method for improving the light efficiency of a display device.

However, difficulties exist in improving the light efficiency of a light emitting element.

### SUMMARY

Embodiments of the present disclosure may provide a display device capable of improving light extraction efficiency.

Embodiments of the present disclosure may provide a display device capable of low-power driving through high luminance characteristics.

In one embodiment, a semiconductor device comprises: a substrate including a plurality of subpixels; an insulating layer on the substrate and including a plurality of concave portions that extend through a thickness of the insulating layer, the plurality of concave portions including a first concave portion in a first subpixel from the plurality of subpixels and a second concave portion in a second subpixel from the plurality of subpixels; a bank layer on the insulating layer and including a plurality of openings, the plurality of openings including a first opening that overlaps the first concave portion and a second opening that overlaps the second concave portion; and a plurality of lens parts over the insulating layer and the bank layer, the plurality of lens parts including a first lens part that overlaps the first concave portion and the first opening and a second lens part that overlaps the second concave portion and the second opening, wherein an area of the first concave portion is larger than an area of the second concave portion.

In one embodiment, a semiconductor device comprises: a substrate; an insulating layer on the substrate and including a plurality of concave portions that extend through a thickness of the insulating layer and are in a plurality of subpixels, each of the plurality of concave portions including a flat portion and a sloped portion that extends from the flat portion and surrounds the flat portion; a bank layer on the insulating layer and including a plurality of opening areas that are each in a corresponding subpixel from the plurality of subpixels, the plurality of opening areas including a first opening area in a first subpixel from the plurality of subpixels that is surrounded by a first concave portion from the plurality of concave portions and a second opening area in a second subpixel from the plurality of subpixels that is surrounded by a second concave portion from the plurality of concave portions; and a plurality of lens parts over the bank layer and the insulating layer, the plurality of lens parts including a first lens part that overlaps the first opening area and the first concave portion and a second lens part that overlaps the second opening area and the second concave portion, wherein the first opening area is wider than the second opening area.

In one embodiment, a display device comprises: a substrate; a plurality of transistors on the substrate, the plurality of transistors including a first transistor; a first insulating layer on the plurality of transistors, the first insulating layer including a first concave portion through a thickness of the first insulating layer; a first light emitting element that is in the first concave portion, the first light emitting element connected to the first transistor and including a first electrode layer in the first concave portion, a first light emitting layer on the first electrode layer in the first concave portion, and a first portion of a second electrode layer on the first light emitting layer in the first concave portion; a bank layer on the first insulating layer, the bank layer including a first opening that extends into the first concave portion; and a plurality of lens parts over the first insulating layer, the plurality of lens parts including a first lens part that overlaps the first concave portion and the first opening.

According to the embodiments of the present disclosure, it is possible to provide a display device capable of improving light extraction efficiency.

According to the embodiments of the present disclosure, it is possible to provide a display device capable of low-power driving through high luminance characteristics.

### BRIEF DESCRIPTION OF DRAWINGS

FIG. 1A is a plan view in a narrow viewing angle mode of a switchable privacy mode as an example according to an embodiment of the present disclosure.

FIG. 1B is a plan view in a wide viewing angle mode of the switchable privacy mode as another example according to the embodiment of the present disclosure.

FIG. 2 is an example diagram of a display device according to embodiments of the present disclosure when the display device senses a touch in a self capacitance-based touch sensing method.

FIG. 3 is a plan view illustrating subpixels disposed in an active area of a display device according to an embodiment of the present disclosure.

FIG. 4 is a plan view illustrating subpixels disposed in an active area of a display device according to another embodiment of the present disclosure.

FIG. 5 is an enlarged plan view of an area PG1 of FIG. 3 according to an embodiment of the present disclosure.

FIG. 6 is an enlarged plan view of an area PG2 of FIG. 4 according to an embodiment of the present disclosure.

FIG. 7 is a plan view showing a display device operating method depending on a mode of a switchable privacy mode in a display device according to embodiments of the present disclosure.

FIG. 8A is a perspective view illustrating a first lens part of a display device according to an embodiment of the present disclosure.

FIG. 8B is a perspective view illustrating a second lens part of the display device according to the embodiment of the present disclosure.

FIG. 9A is an enlarged plan view of an example of a subpixel SP1 of FIG. 5 according to an embodiment of the present disclosure.

FIG. 9B is an enlarged plan view of an example of a subpixel SP2 of FIG. 5 according to an embodiment of the present disclosure.

FIG. 9C is an enlarged plan view of another example of the subpixel SP1 of FIG. 5 according to an embodiment of the present disclosure.

FIG. 10 is a cross-sectional view taken along the line A-A′ of FIG. 6 according to an embodiment of the present disclosure.

FIG. 11 is a cross-sectional view taken along the line B-B′ of FIG. 9A according to an embodiment of the present disclosure.

FIG. 12 is a cross-sectional view taken along the line C-C′ of FIG. 9A according to an embodiment of the present disclosure.

FIG. 13 is a cross-sectional view taken along the line D-D′ of FIG. 9C according to an embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to accompanying drawings.

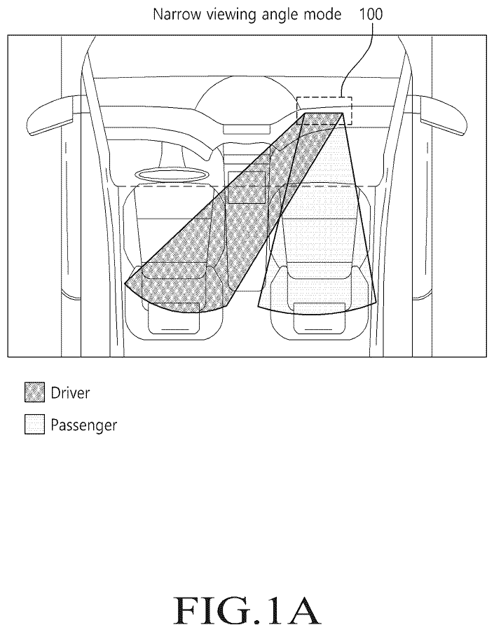

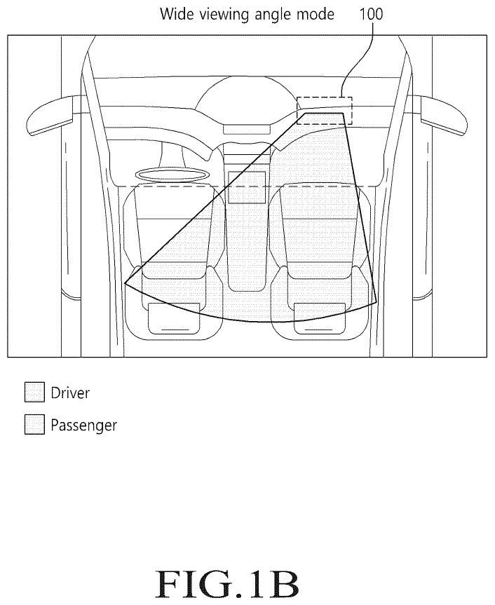

FIGS. 1A and 1B are plan views in a narrow viewing angle mode and a wide viewing angle mode of a switchable privacy mode when a display device 100 (e.g., a semiconductor device) to which the switchable privacy mode is applied is installed in front of a passenger seat as an example according to an embodiment of the present disclosure.

As illustrated in FIGS. 1A and 1B, the display device 100 capable of switching between the wide viewing angle mode and the narrow viewing angle mode may be installed in front of the passenger seat of a car.

However, a place where the display device 100 is to be installed is not limited to the front of the passenger seat, but the display device 100 may be disposed in various places such as the front of a driver seat, the back of the passenger seat and the back of the driver seat. A location where the display device 100 is to be installed is not limited to a car, and the display device 100 may be applied to any locations where privacy is required.

As illustrated in FIG. 1A, during the narrow viewing angle mode, the display device 100 provides an image with luminance of at least 1% (e.g., a first luminance) to a passenger, but provides an image with luminance of less than 1% (e.g., a second luminance) to a driver.

In other words, since the field of view is secured only for the passenger sitting on the passenger seat and is not secured for the driver sitting on the driver seat, the privacy of only the passenger sitting on the passenger seat may be ensured. Thus, the image is displayed with a first viewing angle during the narrow viewing angle mode.

As illustrated in FIG. 1B, during the wide viewing angle mode, the display device 100 provides an image with luminance of at least 1% to both the passenger and the driver to provide an image that may be shared by both the passenger and the driver.

In other words, in the wide viewing angle mode, the field of view may be secured for not only the passenger sitting on the passenger seat but also the driver sitting on the driver seat. Thus, the image is displayed with a second viewing angle that is greater than the first viewing angle during the wide viewing angle mode.

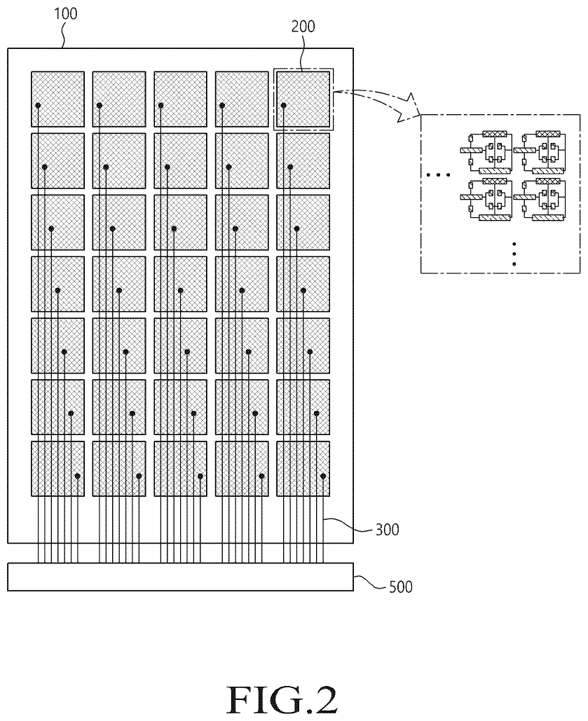

FIG. 2 is an example diagram of a display device 100 according to embodiments of the present disclosure when the display device 100 senses a touch in a self capacitance-based touch sensing method.

Referring to FIG. 2, in the case of the self capacitance-based touch sensing method, each touch sensor 200 disposed in the display device 100 serves as both a driving touch electrode (which is applied with a driving signal) and a sensing touch electrode (which detects a sensing signal).

In other words, a driving signal is applied to each touch sensor 200, and a sensing signal is received through the touch sensor 200 to which the driving signal is applied.

Therefore, in the self capacitance-based touch sensing method, there is no distinction between a driving electrode and a sensing electrode.

In the case of the self capacitance-based touch sensing method, a touch sensing circuit applies a driving signal to at least one touch sensor 200, receives a sensing signal from the touch sensor 200 to which the driving signal is applied, and from the received sensing signal, detects the presence or absence of a touch and/or touch coordinates on the basis of a change in capacitance between a pointer such as a finger or a pen and the touch sensor 200.

Referring to FIG. 2, in order to transfer the driving signal and the sensing signal, each of a plurality of touch sensors 200 may be electrically connected to a pad 500 through at least one touch line 300.

The pad 500 to which the touch line 300 is connected may be connected to the touch sensing circuit (not shown).

The touch sensing circuit may supply a touch driving signal to at least one of the plurality of touch sensors 200, and may detect at least one of the presence or absence of a touch and a touch position as a response to the touch driving signal.

Referring to FIG. 2, the plurality of touch sensors 200 may be located on a plurality of subpixels which are located on a substrate.

The disposition of the plurality of subpixels shown in FIG. 2 is nothing but a mere example and is not necessarily limited thereto.

Referring to FIG. 2, each of the plurality of touch sensors 200 may have, for example, a diamond shape when viewed on an outline. In some cases, each of the plurality of touch sensors 200 may have a rectangular shape (that may include a square shape), and besides, may have various shapes.

FIG. 2 illustrates the self capacitance-based touch sensing method, but this is nothing but a mere example. The touch sensing method of the display device 100 is not necessarily limited thereto. For another example, a mutual capacitance-based touch sensing method may be used.

When the touch sensing method of the display device 100 is the mutual capacitance-based touch sensing method, a plurality of connection patterns to be electrically connected to at least one of a plurality of touch sensors may be included.

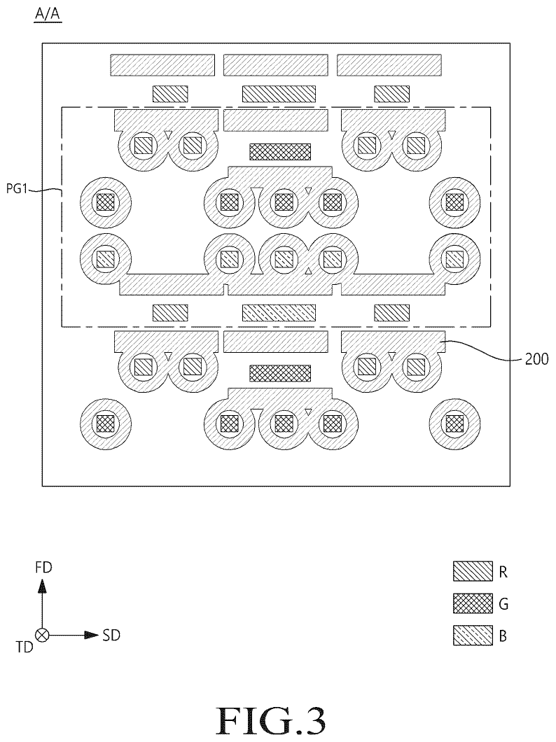

FIG. 3 is a plan view illustrating subpixels disposed in an active area of a display device according to an embodiment of the present disclosure.

Referring to FIG. 3, pixels disposed in an active area A/A of the display device may include subpixels of different colors in order for color implementation of an image.

The subpixels may include a red subpixel R, a green subpixel G and a blue subpixel B.

Although each of the subpixels may further include a white subpixel, FIG. 3 illustrates as an example a case where the plurality of subpixels include a red subpixel R, a green subpixel G and a blue subpixel B.

The plurality of subpixels may include subpixels which have different areas to realize a switchable privacy mode.

For example, on a plane defined by a first direction FD and a second direction SD, a plurality of subpixels including a first subpixel and a second subpixel with an area smaller than the first subpixel may be located in the active area A/A on a substrate.

In this way, by differently designing the size and disposition of subpixels included in a first pixel group PG1 among the subpixels disposed in the active area A/A of the display device of FIG. 3, a privacy protection mode system capable of switching between a wide viewing angle mode and a narrow viewing angle mode may be implemented.

Although the size and disposition of the subpixels for implementing the switchable privacy mode are not specifically limited, FIG. 3 illustrates as an example that four first subpixels with a wide area and 14 second subpixels with a narrow area are disposed in the first pixel group PG1.

Each of the subpixels may include a pixel circuit and a light emitting element.

Referring to FIG. 3, a plurality of touch sensors 200 may be disposed in at least a portion of an area other than an area where the plurality of subpixels are disposed. That is, the touch sensors 200 are non-overlapping with the subpixels in the plane view.

The plurality of touch sensors 200 shown in FIG. 3 may operate in a self capacitance-based touch sensing method, may operate in a mutual capacitance-based touch sensing method, or may operate in various touch sensing methods to which the touch sensors 200 may be applied.

The disposition of the plurality of touch sensors 200 shown in FIG. 3 is an example to show that the plurality of touch sensors 200 are disposed in at least a portion of the area other than the area where the plurality of subpixels are disposed, but the embodiment of the present disclosure is not necessarily limited to such a disposition or shape. The plurality of touch sensors 200 may cover the entire area or a partial area of the active area A/A, or the touch sensors 200 may not be disposed.

The plurality of touch sensors 200 may have a mesh shape with openings depending on the disposition of each of the subpixels.

Each of the plurality of touch sensors 200 in FIG. 3 may have a shape with an opening depending on the disposition of a lens part disposed on each subpixel, and may have a shape with at least two openings connected to each other.

In order to improve the sensing of a touch sensor, in the case of a small-sized subpixel, the subpixel may be disposed in the opening of the touch sensor, but in the case of a subpixel which is relatively larger in size or is rectangular not to be disposed in the same opening, the touch sensor may be disposed to be parallel to the long side of the subpixel. Since the plurality of touch sensors may be formed independently of each other depending on the shape and disposition of each subpixel, the respective touch sensors are electrically connected using connection patterns (not shown).

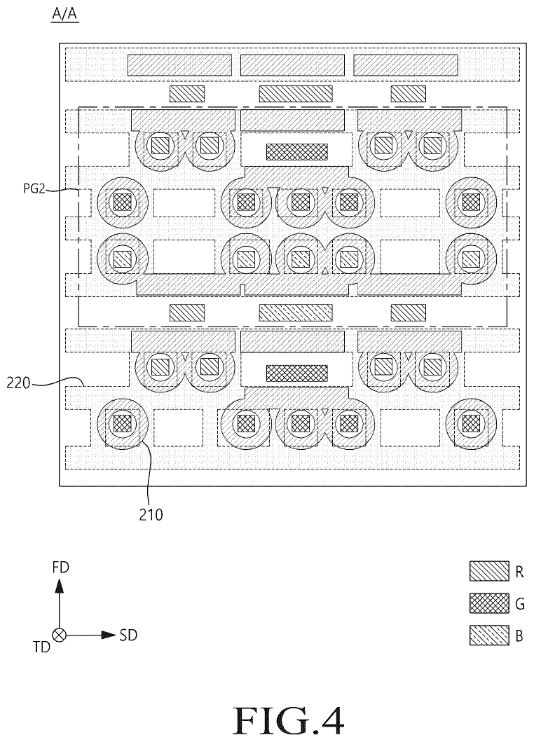

FIG. 4 is a plan view illustrating subpixels disposed in an active area of a display device according to another embodiment of the present disclosure.

Referring to FIG. 4, in the active area A/A of FIG. 3, a plurality of black matrices 220 disposed in at least a portion of the area other than the area where the plurality of subpixels are disposed may be included.

Referring to FIG. 4, the plurality of touch sensors 210 which are disposed in at least a portion of the area other than the area where the plurality of subpixels are disposed and the plurality of black matrices 220 which are disposed in at least a portion of the area other than the area where the plurality of subpixels are disposed may be disposed, and some areas of the plurality of touch sensors 210 and the plurality of black matrices 220 may overlap each other. That is, the touch sensors 210 and the black matrices 220 are non-overlapping with the subpixels and the lens part LEN. The plurality of black matrices 220 may have a mesh shape with openings of different sizes and shapes according to the disposition of each subpixel of a different size and shape. In the case of a subpixel in which the touch sensor 210 is disposed parallel to the long side of the subpixel, the black matrix 220 is also disposed parallel to the long side of the subpixel to cover the touch sensor 210, and the short side of the subpixel may not be surrounded by the black matrix 220.

However, this is nothing but a mere example, and the embodiment of the present disclosure is not necessarily limited thereto. When viewed on a plane defined by the first direction FD and the second direction SD, the touch sensor 210 and the black matrix 220 may be disposed to completely overlap each other, or may be disposed not to overlap each other. Thus, various dispositions may be possible.

In addition, on the plurality of subpixels in the active area A/A, only the black matrices 220 may be disposed, only the touch sensors 210 may be disposed, or neither the black matrices 220 nor the touch sensors 210 may be disposed.

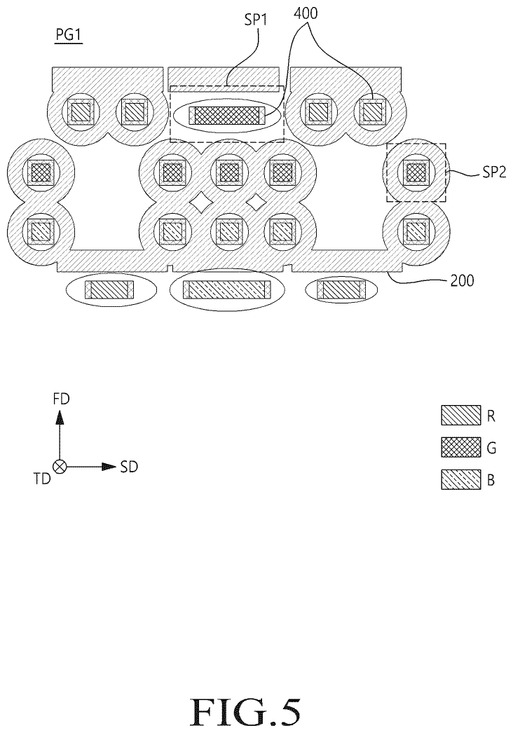

FIG. 5 is an enlarged plan view of an area PG1 of FIG. 3 according to one embodiment.

Referring to FIG. 5, the display device may include a plurality of concave portions 400 which are located in the plurality of subpixels, respectively.

The first pixel group PG1 may include a plurality of first subpixels SP1 and a plurality of second subpixels SP2.

Some of the subpixels SP1 and SP2 may emit light of different colors.

For example, the first subpixels SP1 may be composed of a red subpixel R, a green subpixel G and a blue subpixel B, and may emit light of red, green and blue colors, respectively.

For example, the second subpixels SP2 may be composed of a red subpixel R, a green subpixel G and a blue subpixel B, and may emit light of red, green and blue colors, respectively.

The disposition of the subpixels SP1 and SP2 including the red subpixels R, the green subpixels G and the blue subpixels B as shown in the plan view of FIG. 5 is nothing but a mere example. The embodiment of the present disclosure is not necessarily limited to the disposition, and disposition to various combinations may be envisaged.

Subpixels which emit light of different colors may include opening areas with different areas.

For example, the area of an opening area which emits blue light may be the largest, and the area of an opening area which emits red light may be the smallest.

This is because the characteristics of light emitting elements included in subpixels which emit light of different colors may be different from each other.

However, the embodiment of the present disclosure is not necessarily limited thereto, and the areas of opening areas may be the same regardless of color.

Referring to FIG. 5, a concave portion 400 disposed in the first subpixel SP1 may surround a portion of an opening area in the first subpixel SP1, and a concave portion 400 disposed in the second subpixel SP2 may surround an opening area in the second subpixel SP2.

The fact that the concave portion surrounds the second subpixel SP2 means that when, viewed on a plane defined by the first direction FD and the second direction SD, the concave portion completely surrounds the outer periphery of the opening area in the second subpixel SP2.

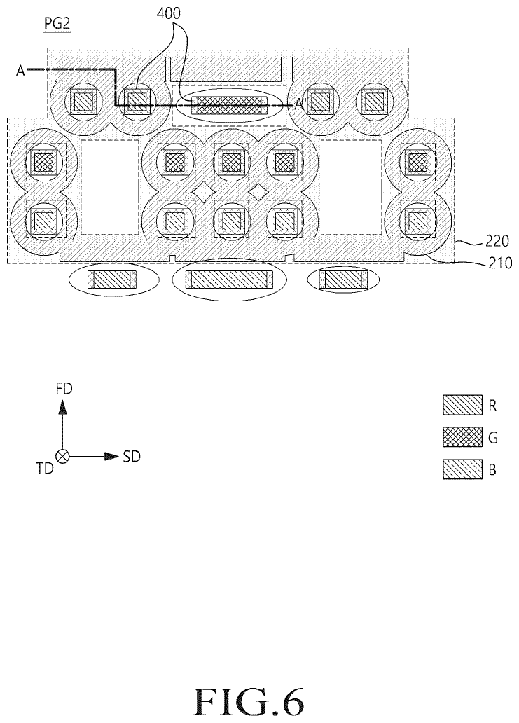

FIG. 6 is an enlarged plan view of an area PG2 of FIG. 4 according to an embodiment of the present disclosure.

Referring to FIG. 6, a second pixel group PG2 may be regarded as further including the black matrices 220 in the first pixel group PG1 of FIG. 5.

In FIG. 6, the plurality of subpixels and concave portions disposed in the plurality of subpixels, respectively, may be substantially the same as the plurality of subpixels and the concave portions disposed in the plurality of subpixels, respectively, described with reference to FIG. 5.

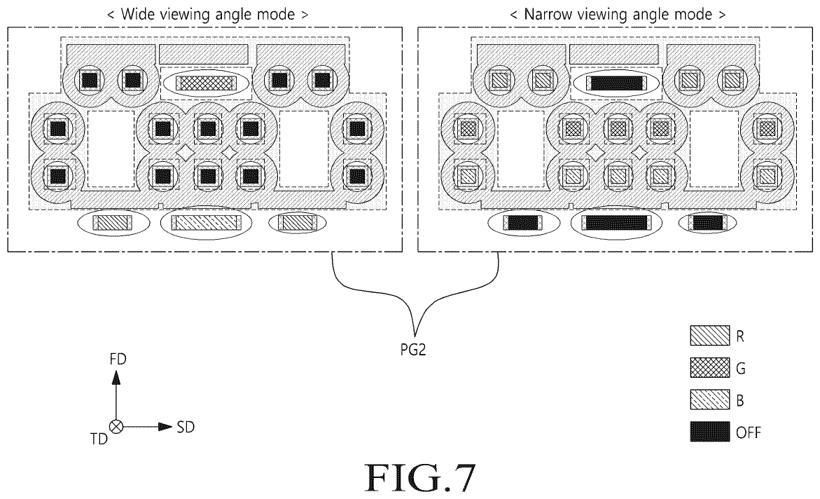

FIG. 7 is a plan view showing a display device operating method depending on a mode of a switchable privacy mode in a display device 100 according to embodiments of the present disclosure.

FIG. 7 will be described by taking the case of the second pixel group PG2 of FIG. 6 as an example, and the description will be made as an example for explaining a switchable privacy mode. However, the description is not necessarily applied only to the second pixel group PG2, but may be applied to the case of the first pixel group GP1 and may also be applied to other pixel groups.

Referring to FIG. 7, the switchable privacy mode may be converted into a wide viewing angle mode and a narrow viewing angle mode according to the convenience of a user (for example, the passenger or the driver of FIGS. 1A and 1B).

In the case of the wide viewing angle mode, in order to secure a wide viewing angle, light may be emitted from the light emitting area of the first subpixel SP1 which has a wider area, and light may not be emitted from the light emitting area of the second subpixel SP2 which has a narrower area than the first subpixel SP1 (OFF).

In the case of the narrow viewing angle mode, in order to secure a narrow viewing angle, light may not be emitted from the light emitting area of the first subpixel SP1 which has a wider area (OFF), and light may be emitted from the light emitting area of the second subpixel SP2 which has a narrower area than the first subpixel SP1.

When the display device 100 is installed in front of the passenger seat, in the wide viewing angle mode, the field of view may be secured not only for the passenger sitting on the passenger seat but also for the driver sitting on the driver seat. That is, both the passenger and driver view and image during the wide viewing angle mode.

In the narrow viewing angle mode, since the field of view is secured for only the passenger sitting on the passenger seat and is not secured for the driver sitting on the driver seat, privacy protection for only the passenger sitting on the passenger seat may be achieved. That is, the passenger views an image without the driver viewing the image during the narrow viewing angle mode.

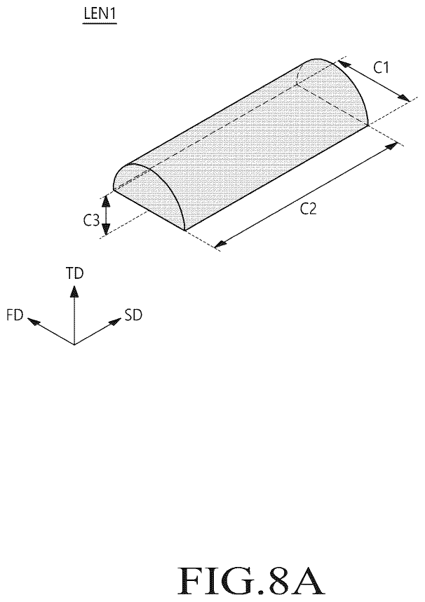

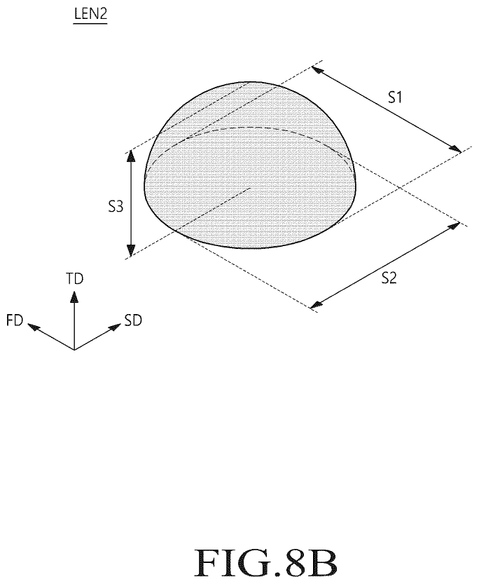

FIGS. 8A and 8B are perspective views illustrating a first lens part LEN1 and a second lens part LEN2, respectively, of a display device according to an embodiment of the present disclosure.

Referring to FIG. 8A, the first lens part LEN1 corresponding to the first subpixel SP1 may have a semicylindrical shape with a diameter C1 in the first direction FD, a length C2 in the second direction SD and a height C3 in a third direction TD.

In the first lens part LEN1, the length C2 in the second direction SD may be larger than the diameter C1 in the first direction FD.

Although the first lens part LEN1 of FIG. 8A has a semicylindrical shape, the shape is nothing but a mere example, and the embodiment of the present disclosure is not necessarily limited to the shape. Various shapes may be possible depending on the shape of the opening area of the first subpixel SP1.

For example, the height C3 in the third direction TD may be half the diameter C1 in the first direction FD, but is not necessarily limited thereto. The height C3 in the third direction TD may be larger or smaller than half the diameter C1 in the first direction FD.

Referring to FIG. 8B, the second lens part LEN2 corresponding to the second subpixel SP2 may have a hemispherical shape with a diameter S1 in the first direction FD, a diameter S2 in the second direction SD and a height S3 in the third direction TD.

In the second lens part LEN2, the diameter S2 in the second direction SD and the diameter S1 in the first direction FD may be the same.

Although the second lens part LEN2 of FIG. 8B has a hemispherical shape, the shape is nothing but a mere example, and the embodiment of the present disclosure is not necessarily limited to the shape. Various shapes may be possible depending on the shape of the opening area of the second subpixel SP2.

For example, the height S3 in the third direction TD may be half the diameter S1 in the first direction FD, but is not necessarily limited thereto. The height C3 in the third direction TD may be larger or smaller than half the diameter S1 in the first direction FD.

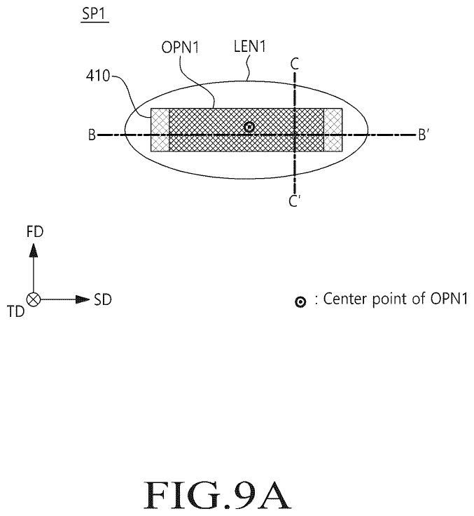

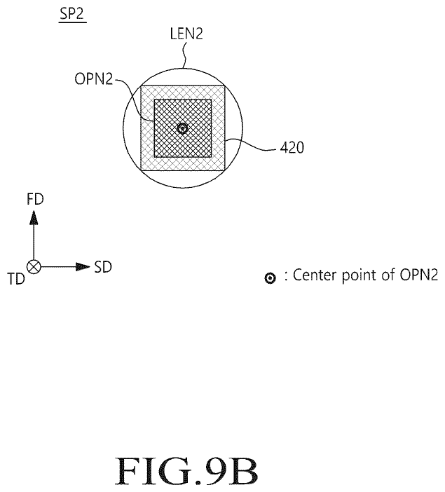

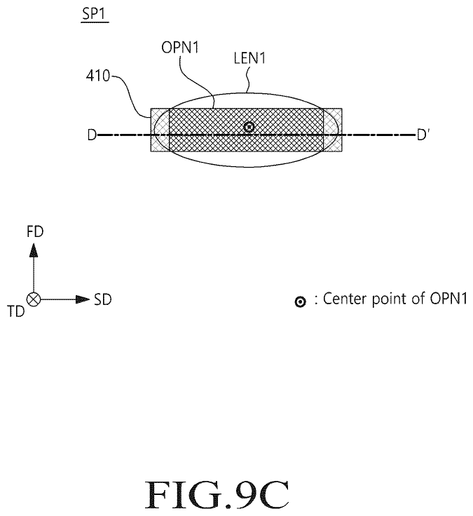

FIGS. 9A and 9B are enlarged plan views of examples of subpixels SP1 and SP2 of FIG. 5 according to one embodiment.

In describing the first and second subpixels SP1 and SP2 of FIGS. 9A and 9B, touch sensors are omitted.

Referring to FIG. 9A, the first subpixel SP1 may include a first opening area OPN1 in the first subpixel SP1 and a first concave portion 410 which surrounds the first opening area OPN1. The first concave portion 410 may be formed along the short sides (e.g., first sides) of the first opening area OPN1 but not the long sides (e.g., second sides) of the first opening. However, the embodiment of the present disclosure is not necessarily limited thereto.

The first concave portion 410 may be formed along the long sides of the first opening area OPN1, may be formed to surround both the short sides and the long sides, and may be formed in various shapes. FIG. 9A illustrates as an example that the first concave portion 410 is formed along the short sides of the first opening area OPN1.

The first concave portion 410 may be composed of a flat portion and a sloped portion which surrounds the flat portion.

The first opening area OPN1 may be surrounded by the sloped portion of the first concave portion 410.

The light emitting area of the first subpixel SP1 may be defined by the first opening area OPN1.

Namely, the light emitting area of the first subpixel SP1 may be substantially the same as the first opening area OPN1.

Being substantially the same in the present disclosure may mean the same degree in consideration of a minute difference due to an error in a process.

The first subpixel SP1 may include a first lens part LEN1 corresponding to the first opening area OPN1. That is, the first lens part LEN1 overlaps the first opening area OPN1.

The first lens part LEN1 of FIG. 9A may be substantially the same as the first lens part LEN1 described with reference to FIG. 8A.

The first lens part LEN1 may cover the first opening area OPN1 in the first subpixel SP1 and the concave portion 410 disposed in the first subpixel SP1.

The fact that the first lens part LEN1 covers the concave portion 410 disposed in the first subpixel SP1 is a concept including both the case of covering the entirety of the concave portion 410 and the case of covering a portion of the concave portion 410.

The first lens part LEN1 is to improve light efficiency by changing the optical path of light emitted from the first opening area OPN1. The first lens part LEN1 may be located to correspond to the first opening area OPN1, and the shape of the first lens part LEN1 may also correspond to the shape of the first opening area OPN1. That is, the shape of the first lens part LEN1 has a same shape as the first opening area OPN1. However, the shape of the first lens part LEN1 is not necessarily limited to the shape of the first opening area OPN1, and various shapes may be possible.

Referring to FIG. 9A, the concave portion 410 disposed in the first subpixel SP1 may surround portions of the first opening area OPN1 in the first subpixel SP1.

In the embodiment of FIG. 9A, when viewed on a plane defined by the first direction FD and the second direction SD perpendicular to the first direction FD, the distance (e.g., a first distance) between two points (e.g., a first pair of points) at which an imaginary straight line (e.g., a first imaginary straight line) passing through the center point of the first opening area OPN1 in the first subpixel SP1 and parallel to the second direction SD meets the boundaries of the first opening area OPN1 in the first subpixel SP1 may be longer than the distance (e.g., a second distance) between two points (e.g., a second pair of points) at which an imaginary straight line (e.g., a second imaginary straight line) passing through the center point of the first opening area OPN1 in the first subpixel SP1 and parallel to the first direction FD meets the boundaries of the first opening area OPN1 in the first subpixel SP1, and the first concave portion 410 disposed in the first subpixel SP1 may include the two points at which the imaginary straight line passing through the center point of the first opening area OPN1 in the first subpixel SP1 and parallel to the second direction SD meets the boundaries of the first opening area OPN1 in the first subpixel SP1.

In the present specification, a center point may mean the geometric center of an area having a random area when viewed on a plane defined by the first direction FD and the second direction SD perpendicular to the first direction FD.

For example, the center point of the first opening area OPN1 in FIG. 9A may mean the intersection of two diagonals that connect opposing vertices of the first opening area OPN1.

The center point of the first opening area OPN1 is located inside the first opening area OPN1.

When the first concave portion 410 is disposed in the embodiment of FIG. 9A described above, light extraction occurs widely in the second direction SD by the first concave portion 410, and at the same time, viewing angle in the first direction FD is reduced by the first lens part LEN1 while the luminance viewing angle is improved in the second direction SD, whereby the wide viewing angle mode desired by the user may be realized.

Referring to FIG. 9B, the second subpixel SP2 may include a second opening area OPN2 in the second subpixel SP2 and a second concave portion 420 which surrounds the second opening area OPN2.

The second concave portion 420 may be composed of a flat portion and a sloped portion which surrounds the flat portion.

The second opening area OPN2 may be surrounded by the sloped portion of the second concave portion 420.

The light emitting area of the second subpixel SP2 may be defined by the second opening area OPN2.

Namely, the light emitting area of the second subpixel SP2 may be substantially the same as the second opening area OPN2.

The second subpixel SP2 may include a second lens part LEN2 corresponding to the second opening area OPN2. That is, the second lens part LEN2 overlaps the second opening area OPN2.

The second lens part LEN2 of FIG. 9B may be substantially the same as the second lens part LEN2 described with reference to FIG. 8B.

The second lens part LEN2 is to improve light efficiency by changing the optical path of light emitted from the second opening area OPN2. The second lens part LEN2 may be located to correspond to the second opening area OPN2, and the shape of the second lens part LEN2 may also correspond to the shape of the second opening area OPN2. That is, the shape of the second lens part LEN2 has a same shape as the second opening area OPN2. However, the shape of the second lens part LEN2 is not necessarily limited to the shape of the second opening area OPN2, and various shapes may be possible.

Referring to FIG. 9B, the second concave portion 420 disposed in the second subpixel SP2 may surround the second opening area OPN2 in the second subpixel SP2.

In the embodiment of FIG. 9B, when viewed on a plane defined by the first direction FD and the second direction SD perpendicular to the first direction FD, the distance between two points at which an imaginary straight line passing through the center point of the second opening area OPN2 in the second subpixel SP2 and parallel to the first direction FD meets the boundaries of the second opening area OPN2 in the second subpixel SP2 may be the same as the distance between two points at which an imaginary straight line passing through the center point of the second opening area OPN2 in the second subpixel SP2 and parallel to the second direction SD meets the boundaries of the second opening area OPN2 in the second subpixel SP2.

When the second concave portion 420 is disposed in the embodiment of FIG. 9B described above, light extraction may be maximized as the second opening area OPN2 is surrounded by the sloped portion of the second concave portion 420, and viewing angle in the first direction FD may be reduced and light may be collected toward the front through the second lens part LEN2, whereby the narrow viewing angle mode desired by the user may be realized.

FIG. 9C is an enlarged plan view of another example of the subpixel SP1 of FIG. 5 according to one embodiment.

An opening area OPN1 and a first concave portion 410 in the first subpixel SP1 of FIG. 9C are substantially the same as the opening area OPN1 and the first concave portion 410 in the first subpixel SP1 described with reference to FIG. 9A.

Referring to FIG. 9C, the first lens part LEN1 may cover the opening area OPN1 in the first subpixel SP1, and may cover a portion of the first concave portion 410 disposed in the first subpixel SP1 without covering the first concave portion 410 in its entirety. Thus, a part of the first concave portion 410 is non-overlapping with the first lens part LEN1.

When the first lens part LEN1 is designed as shown in FIG. 9C described above, the first lens part LEN1 extracts light emitted through the opening area OPN1 in the first subpixel SP1, and light emitted by the first concave portion 410 is not extracted by the first lens part LEN1.

Accordingly, since light emitted by the first concave portion 410 is not extracted by the first lens part LEN1, luminance efficiency decreases, but a viewing angle in the second direction SD increases, whereby the enhanced wide viewing angle mode may be realized.

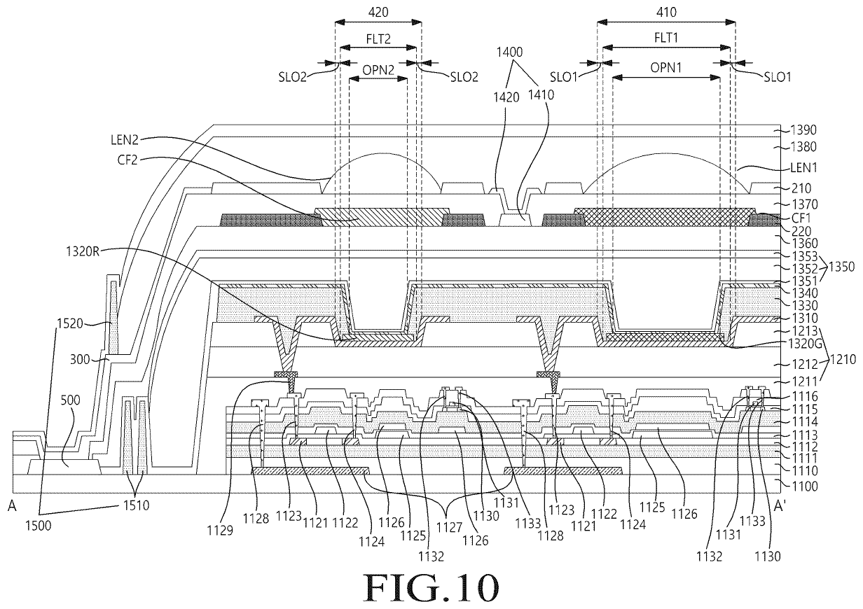

FIG. 10 is a cross-sectional view taken along the line A-A′ of FIG. 6 according to one embodiment.

FIG. 10 may be a view illustrating a plurality of subpixel areas in a display device according to embodiments of the present disclosure, and may be a view illustrating a part of a non-active area.

Referring to FIG. 10, the display device according to the embodiments of the present disclosure includes a substrate 1100, an insulating layer 1210 located on the substrate 1100, a first electrode layer 1310 located on the insulating layer 1210, a bank layer 1330 located on the first electrode layer 1310 and the insulating layer 1210, a light emitting layer 1320 located on the first electrode layer 1310, a second electrode layer 1340 located on the light emitting layer 1320 and the bank layer 1330, an encapsulation layer 1350 located on the second electrode layer 1340, a touch buffer layer 1360 located on the encapsulation layer 1350, a touch interlayer insulating layer 1370 located on the touch buffer layer 1360, and a planarization layer 1380 located on the touch interlayer insulating layer 1370.

In an active area, the display device may include a first transistor located on the substrate 1100 and an organic light emitting element electrically connected to the first transistor.

The first transistor may include a first active layer 1121, a first gate electrode layer 1122, a first source electrode layer 1123 and a first drain electrode layer 1124.

The organic light emitting element includes the first electrode layer 1310, the light emitting layer 1320 and the second electrode layer 1340.

The first electrode layer 1310 may be an anode electrode layer and the second electrode layer 1340 may be a cathode electrode layer, but the embodiments of the present disclosure are not limited thereto.

Specifically, a first metal pattern 1127 may be disposed on the substrate 1100.

A first buffer layer 1110 may be disposed on the substrate 1100 and the first metal pattern 1127, and a second buffer layer 1111 may be disposed on the first buffer layer 1110.

The first active layer 1121 of the first transistor may be disposed on the second buffer layer 1111.

A first gate insulating layer 1112 may be disposed on the first active layer 1121, and the first gate electrode layer 1122 may be disposed on the first gate insulating layer 1112.

A first interlayer insulating layer 1113 may be disposed on the first gate electrode layer 1122, a third buffer layer 1114 may be disposed on the first interlayer insulating layer 1113, a second gate insulating layer 1115 may be disposed on the third buffer layer 1114, and a second interlayer insulating layer 1116 may be disposed on the second gate insulating layer 1115.

A second metal pattern 1128, the first source electrode layer 1123 and the first drain electrode layer 1124 may be disposed on the second interlayer insulating layer 1116.

The first source electrode layer 1123 and the first drain electrode layer 1124 may be disposed to be spaced apart from each other on the second interlayer insulating layer 1116.

Each of the first source electrode layer 1123 and the first drain electrode layer 1124 may contact the first active layer 1121 through holes formed in the first gate insulating layer 1112, the first interlayer insulating layer 1113, the third buffer layer 1114, the second gate insulating layer 1115 and the second interlayer insulating layer 1116.

Although the first transistor may be disposed on the substrate 1100 as described above, but the structure of the first transistor according to the embodiments of the present disclosure is not limited thereto.

For another example, the first gate electrode layer 1122 may be disposed on the substrate 1100, the first active layer 1121 may be disposed on the first gate electrode layer 1122, and on the first active layer 1121, the first source electrode layer 1123 may be disposed to overlap one end of the first active layer 1121 and the first drain electrode layer 1124 may be disposed to overlap the other end of the first active layer 1121.

The insulating layer 1210 may be disposed to cover the first transistor.

The insulating layer 1210 may be made of an organic material, but the embodiments of the present disclosure are not limited thereto.

The insulating layer 1210 may include a first insulating layer 1211, a second insulating layer 1212 and a third insulating layer 1213.

Specifically, the first insulating layer 1211 which covers the first transistor may be disposed, the second insulating layer 1212 may be disposed on the first insulating layer 1211, and the third insulating layer 1213 may be disposed on the second insulating layer 1212.

However, the insulating layer 1210 is not necessarily limited thereto. The insulating layer 1210 may be an insulating layer formed as a single layer, and thus, is not limited to a multilayer.

The insulating layer 1210 may be disposed for a plurality of subpixels, and may include a plurality of concave portions 400 which are located in the plurality of subpixels, respectively.

FIG. 10 illustrates as an example a case where the insulating layer 1210 is disposed in the red subpixel R and the green subpixel G and includes a second concave portion 420 and a first concave portion 410 located in the red subpixel R and the green subpixel G, respectively.

The insulating layer 1210 may include a peripheral portion which surrounds the concave portion 400 and is located around the concave portion 400.

The concave portion 400 may be composed of a flat portion FLT and a sloped portion SLO which surrounds the flat portion FLT and extends from the flat portion FLT.

Specifically, the second insulating layer 1212 may include the flat portion FLT, and the third insulating layer 1213 may include the sloped portion SLO. Thus, the opening is formed through the entire thickness of the third insulating layer 1213 which is on the second insulating layer 1212 thereby exposing a portion of the upper surface of the second insulating layer 1212 that corresponds to the flat portion FLT and exposing a portion of the side surfaces of the third insulating layer 1213 which correspond to the sloped portion SLO.

However, the embodiments of the present disclosure are not necessarily limited thereto, and one insulating layer 1210 may include both the flat portion FLT and the sloped portion SLO of the concave portion 400.

The flat portion FLT of the concave portion 400 may be a portion whose surface is parallel to the surface of the substrate 1100, and the sloped portion SLO may be a portion which surrounds the flat portion FLT and whose surface has a predetermined angle with respect to the surface of the substrate 1100.

That is to say, the surface of the sloped portion SLO may not be parallel to the surface of the substrate 1100.

The first concave portion 410 may be composed of a first flat portion FLT1 and a first sloped portion SLO1 which surrounds the first flat portion FLT1.

The second concave portion 420 may be composed of a second flat portion FLT2 and a second sloped portion SLO2 which surrounds the second flat portion FLT2.

The insulating layer 1210 may have a contact hole which is spaced apart from the concave portion 400.

In at least one subpixel area, the first electrode layer 1310 is disposed on the peripheral portion and the concave portion 400 of the insulating layer 1210.

In addition, as described above, in at least one subpixel, the insulating layer 1210 may include at least one contact hole which is spaced apart from the concave portion 400, and the first transistor and the first electrode layer 1310 of the organic light emitting element may be electrically connected through the contact hole of the insulating layer 1210.

The bank layer 1330 which is located on the insulating layer 1210 and includes an opening area OPN in at least one subpixel may be disposed. The bank layer 1330 is on the third insulating layer 1213. Thus, the bank layer 1330 includes a plurality of opening areas OPN (e.g., openings) that overlap the concave portions of the second insulating layer 1213. As shown in FIG. 10, each opening area OPN extends into a corresponding concave portion of the second insulating layer 1213.

The bank layer 1330 has the opening area OPN which exposes a portion of the upper surface of the first electrode layer 1310 in an area overlapping the concave portion 400.

The opening area OPN may correspond to a portion of the flat portion FLT.

The fact that the opening area OPN corresponds to a portion of the flat portion FLT may mean that the opening area OPN overlaps the portion of the flat portion FLT in the subpixel.

Accordingly, at least one subpixel may have an area where the first electrode layer 1310 does not overlap the bank layer 1330.

The opening area OPN may include a first opening area OPN1 and a second opening area OPN2.

The first opening area OPN1 in a first subpixel among the plurality of subpixels may be wider than the second opening area OPN2 in a second subpixel among the plurality of subpixels.

The light emitting layer 1320 of the organic light emitting element may be disposed on the first electrode layer 1310 which does not overlap the bank layer 1330.

The light emitting layer 1320 may be disposed between the first electrode layer 1310 and a portion of the bank layer 1330.

The second electrode layer 1340 of the organic light emitting element may be disposed on the light emitting layer 1320.

The light emitting layer 1320 of the organic light emitting element may be formed by a deposition or coating method that has straightness.

For example, the light emitting layer 1320 may be formed by a physical vapor deposition (PVD) method.

The thickness of the light emitting layer 1320 which is formed by this method may be thinner in an area having a predetermined angle with respect to the substrate 1100 than an area parallel to the substrate 1100.

Accordingly, when the organic light emitting element is driven, current density may be highest in an area where the thickness of the light emitting layer 1320 is formed to be relatively thin, that is, an area corresponding to the sloped portion SLO of the concave portion 400, and a strong electric field may be applied in the area corresponding to the sloped portion SLO of the concave portion 400.

Therefore, the light emission characteristics of the organic light emitting element in the area corresponding to the sloped portion SLO of the concave portion 400 and the light emission characteristics of the organic light emitting element in an area corresponding to the flat portion FLT of the concave portion 400 may be different from each other, and degradation of the element may occur.

The light emitting layer 1320 may include a red organic light emitting layer 1320R disposed in the red subpixel R, a green organic light emitting layer 1320G disposed in the green subpixel G, and a blue organic light emitting layer 1320B disposed in the blue subpixel B.

FIG. 10 illustrates a case where the red organic light emitting layer 1320R is disposed in the second subpixel and the green organic light emitting layer 1320G is disposed in the first subpixel, but the embodiments of the present disclosure are not necessarily limited to the configuration.

In the embodiments of the present disclosure, as the bank layer 1330 is disposed to cover the sloped portion SLO of the concave portion 400, it is possible to prevent the degradation of the element from occurring in the area corresponding to the sloped portion SLO of the concave portion 400 and prevent a phenomenon in which light emission characteristics are different in areas.

However, the thickness conditions of the light emitting layer 1320 in the embodiments of the present disclosure are not limited thereto, and the light emitting layer 1320 may have a corresponding thickness at each location.

The first electrode layer 1310 may include a reflective metal.

FIG. 10 illustrates a configuration in which the first electrode layer 1310 is a single layer. However, the embodiments of the present disclosure are not limited thereto, and the first electrode layer 1310 may be composed of a multilayer.

For example, when the first electrode layer 1310 is composed of a multilayer, at least one layer may include a reflective metal.

For example, the first electrode layer 1310 may include at least one of aluminum, neodymium, nickel, titanium, tantalum, copper, silver and aluminum alloy, but the embodiments of the present disclosure are not limited thereto.

The second electrode layer 1340 may include a conductive material that transmits or semi-transmits light.

For example, the second electrode layer 1340 may include at least one type of transparent conductive oxide such as indium tin oxide (ITO), indium zinc oxide (IZO), indium tin zinc oxide (ITZO), zinc oxide and tin oxide, or may include translucent metal such as magnesium, silver and alloy of magnesium and silver.

When the second electrode layer 1340 includes translucent metal, the thickness of the second electrode layer 1340 may be thinner than the thickness of the first electrode layer 1310.

On the substrate 1100, the first metal pattern 1127, the second metal pattern 1128 electrically connected to the first metal pattern 1127 and a third metal pattern 1129 located on the first insulating layer 1211 may be disposed.

The first metal pattern 1127 may perform the function of a capacitor or perform the function of blocking light from a backside.

The second metal pattern 1128 may contact the first metal pattern 1127 through holes formed in the first buffer layer 1110, the second buffer layer 1111, the first gate insulating layer 1112, the first interlayer insulating layer 1113, the third buffer layer 1114, the second gate insulating layer 1115 and the second interlayer insulating layer 1116.

The third metal pattern 1129 may contact the first source electrode layer 1123 through a hole formed in the first insulating layer 1211, and may contact the first electrode layer 1310 through holes formed in the second insulating layer 1212 and the third insulating layer 1213.

In other words, the third metal pattern 1129 may serve to electrically connect the first source electrode layer 1123 and the first electrode layer 1310.

As shown in FIG. 10, a storage capacitor Cst may be disposed in the active area A/A.

The storage capacitor Cst may include a first storage capacitor electrode layer 1125 disposed at the same layer as the first gate electrode layer 1122 and a second storage capacitor electrode layer 1126 disposed on the first interlayer insulating layer 1113, but the structure of the storage capacitor Cst according to the embodiments of the present disclosure is not limited thereto.

As shown in FIG. 10, the second storage capacitor electrode layer 1126 may form a capacitor with a second gate electrode layer 1131 of a second transistor different from the first transistor.

A second active layer 1130 of the second transistor may be disposed on the third buffer layer 1114.

The second gate insulating layer 1115 may be disposed on the second active layer 1130, and the second gate electrode layer 1131 may be disposed on the second gate insulating layer 1115.

The second interlayer insulating layer 1116 may be disposed on the second gate electrode layer 1131, and the insulating layer 1210 may be disposed on the second interlayer insulating layer 1116.

A second source electrode layer 1132 and a second drain electrode layer 1133 may be disposed on the second interlayer insulating layer 1116.

The second source electrode layer 1132 and the second drain electrode layer 1133 may be disposed to be spaced apart from each other on the second interlayer insulating layer 1116.

Each of the second source electrode layer 1132 and the second drain electrode layer 1133 may contact the second active layer 1130 through a hole formed in the second interlayer insulating layer 1116.

The encapsulation layer 1350 as at least one layer may be disposed on the second electrode layer 1340 of the organic light emitting element. As shown in FIG. 10, the encapsulation layer 1350 is between the bank layer 1330 and the lens parts LEN.

The encapsulation layer 1350 may include a first encapsulation layer 1351 disposed on the second electrode layer 1340, a second encapsulation layer 1352 disposed on the first encapsulation layer 1351, and a third encapsulation layer 1353 disposed on the second encapsulation layer 1352.

As such, when the encapsulation layer 1350 is made of a multilayer, at least one layer may include an inorganic insulating material and at least another layer may include an organic insulating material.

In the embodiments of the present disclosure, the first encapsulation layer 1351 and the third encapsulation layer 1353 may include an inorganic insulating material, and the second encapsulation layer 1352 may include an organic insulating material. However, the embodiments of the present disclosure are not limited thereto.

The encapsulation layer 1350 may be disposed on the organic light emitting element to prevent moisture or foreign substances from penetrating into the organic light emitting element.

A plurality of black matrices 220 may be disposed on the third encapsulation layer 1353.

The black matrices 220 may be formed of a material with low reflectivity.

For example, the black matrices 220 may include carbon black, dye or resin.

The touch interlayer insulating layer 1370 may be disposed on the third encapsulation layer 1353 and the black matrices 220.

A plurality of touch sensors 210 may be disposed on the touch interlayer insulating layer 1370.

The touch sensors 210 may be transparent or opaque.

The planarization layer 1380 may be disposed on the plurality of touch sensors 210.

In the display device according to the embodiments of the present disclosure, as the planarization layer 1380 includes a lens part LEN, light trapped in the substrate 1100 by total reflection, etc. may be extracted, and thus, it is possible to provide a display device with excellent luminance.

The refractive index of the planarization layer 1380 may be smaller than the refractive index of the lens part LEN.

In this way, since the refractive index of the planarization layer 1380 is smaller than the refractive index of the lens part LEN, the movement path of light may be adjusted to a desired direction.

The lens part LEN may include a first lens part LEN1 corresponding to the first concave portion 410 disposed in the first subpixel, and a second lens part LEN2 corresponding to the second concave portion 420 disposed in the second subpixel.

The fact that the lens part LEN corresponds to the concave portion 400 may mean that, for example, in one subpixel, the lens part LEN is located to overlap the entirety or a partial area of the concave portion 400.

As the lens part LEN is located in an area corresponding to the concave portion 400, for example, light emitted from the light emitting layer 1320 to be discharged to the outside of the display device and light emitted from the light emitting layer 1320 to be discharged to the outside of the display device by being reflected by the reflective metal included in the first electrode layer 1310 located on the sloped portion SLO of the concave portion 400 may be effectively dispersed. That is, each lens part LEN overlaps a corresponding concave portion 400.

Since light dispersed by the lens part LEN may be extracted to the outside of the display device without being totally reflected at the interface between the display device and external air, the luminance of the display device may be improved by the lens part LEN.

The display device may include a color filter CF located between the touch buffer layer 1360 and a layer at which the plurality of touch sensors 210 are disposed. As shown in FIG. 10, the touch sensor 210 is on a same layer as the lens part LEN and the color filter CF is on a same layer as the black matrices 220. Thus, the touch sensor 210 and the lens part LEN are on a different layer from the color filter CF and the black matrices 220.

In FIG. 10, a green color filter CF1 and a red color filter CF2 are disposed between the touch buffer layer 1360 and the layer at which the plurality of touch sensors 210 are disposed.

By including the color filter CF located between the touch buffer layer 1360 and the layer at which the plurality of touch sensors 210 are disposed, it is possible to provide a display device with high luminance efficiency.

The display device may include a plurality of connection patterns 1400 located at the layer at which the color filter CF and the black matrices 220 are disposed.

In FIG. 10, it is described as an example that one connection pattern 1400 among the plurality of connection patterns 1400 is disposed between the green color filter CF1 and the red color filter CF2.

The connection pattern 1400 may include a first connection pattern 1410 located on the touch buffer layer 1360 and a second connection pattern 1420 electrically connected to at least one of the plurality of touch sensors 210.

The first connection pattern 1410 and the second connection pattern 1420 may contact each other by a hole formed in the touch interlayer insulating layer 1370. As shown in FIG. 10, the first connection pattern 1410 is on a same layer as the color filter CF an the black matrices 220.

The display device may include at least one dam 1500 outside the planarization layer 1380.

Specifically, the display device according to the embodiments of the present disclosure may include a first dam 1510 located outside the encapsulation layer 1350 and a second dam 1520 located outside the planarization layer 1380. As shown in FIG. 10, an end of the planarization layer 1380 contacts the second dam 1520. Furthermore, the first dam 1510 is closer to the substrate 1100 than the second dam 1520 and is between the second dam 1520 and the bank layer 1330 in a cross-section view of the display device.

In the present specification, the first dam 1510 and the second dam 1520 mean a lower dam and an upper dam, respectively.

FIG. 10 illustrates a configuration in which the dam 1500 includes the first dam 1510 and the second dam 1520. However, the embodiments of the present disclosure are not limited thereto, and the number of dams 1500 may be appropriately changed depending on the size of the display device.

In addition, FIG. 10 illustrates a configuration in which the first dam 1510 has two partition walls and the second dam 1520 has one partition wall. However, the embodiments of the present disclosure are not limited thereto and a dam may have various numbers of partition walls.

Because the planarization layer 1380 disposed to planarize the lens part LEN is formed by inkjet printing, by disposing the second dam 1520, it is possible to prevent ink from leaking to the outside of the first dam 1510 during inkjet printing.

At least one touch line 300 may be disposed on the touch interlayer insulating layer 1370.

The touch sensors 210 may be electrically connected through the connection pattern 1400 to form one driving touch electrode line or one sensing touch electrode line.

FIG. 10 illustrates a configuration in which the touch sensors 210 and the touch line 300 are located at the same layer. However, the embodiments of the present disclosure are not limited thereto, and the touch sensors 210 and the touch line 300 may be located at different layers.

The touch line 300 is located on the first dam 1510, and extends to a pad part 500 which is located outside the first dam 1510.

The touch line 300 is electrically connected to the pad part 500.

Specifically, the touch line 300 may be electrically connected to the pad part 500 which is provided in the non-active area N/A.

The pad part 500 to which the touch line 300 is connected may be connected to a touch sensing circuit (not shown).

The touch sensing circuit may supply a touch driving signal to at least one of the plurality of touch sensors 210, and may detect at least one of the presence or absence of a touch and a touch position as a response to the touch driving signal.

The touch line 300, the touch interlayer insulating layer 1370, the touch buffer layer 1360 and the encapsulation layer 1350 may be disposed to overlap the first dam 1510. However, the disposition is nothing but a mere example, and the components may be disposed in a different way.

A passivation layer 1390 may be disposed on the planarization layer 1380 and the second dam 1520.

The passivation layer 1390 may prevent moisture or foreign substances from penetrating and prevent a material such as metal from being corroded by reacting with moisture in the air.

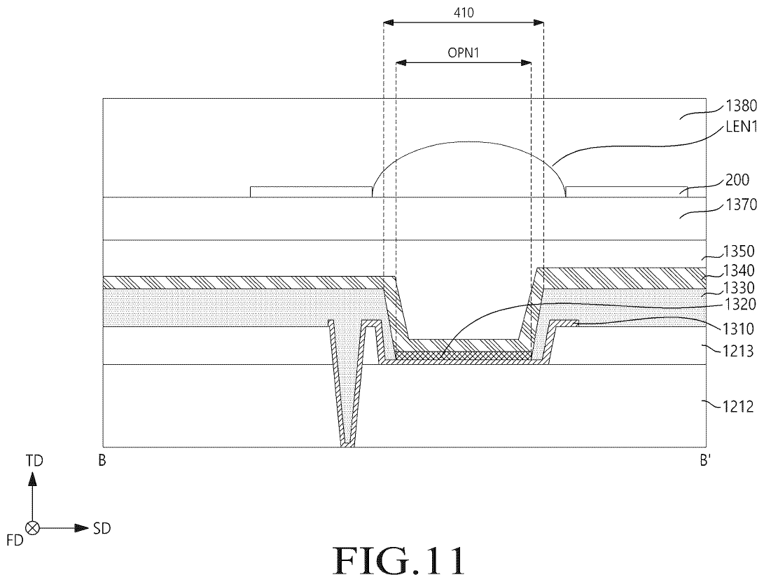

FIG. 11 is a cross-sectional view taken along the line B-B′ of FIG. 9A according to one embodiment.

A first insulating layer (not shown), a second insulating layer 1212, a third insulating layer 1213, a first electrode layer 1310, a light emitting layer 1320, a bank layer 1330, a second electrode layer 1340, an encapsulation layer 1350, a touch buffer layer (not shown), a touch interlayer insulating layer 1370, a planarization layer 1380, a first lens part LEN1 and a touch sensor 210 of FIG. 11 may be substantially the same as the first insulating layer 1211, the second insulating layer 1212, the third insulating layer 1213, the first electrode layer 1310, the light emitting layer 1320, the bank layer 1330, the second electrode layer 1340, the encapsulation layer 1350, the touch buffer layer 1360, the touch interlayer insulating layer 1370, the planarization layer 1380, the first lens part LEN1 and the touch sensor 210 described with reference to FIG. 10.

Referring to FIG. 11, in FIG. 9A, in the case where the concave portion 410 disposed in the first subpixel includes two points at which an imaginary straight line passing through the center point of the opening area OPN1 in the first subpixel and parallel to the second direction SD meets the boundaries of the opening area OPN1 in the first subpixel, light extraction occurs widely in the second direction SD by the concave portion 410, and at the same time, luminance viewing angle is improved in the second direction SD, whereby the wide viewing angle mode desired by the user may be realized.

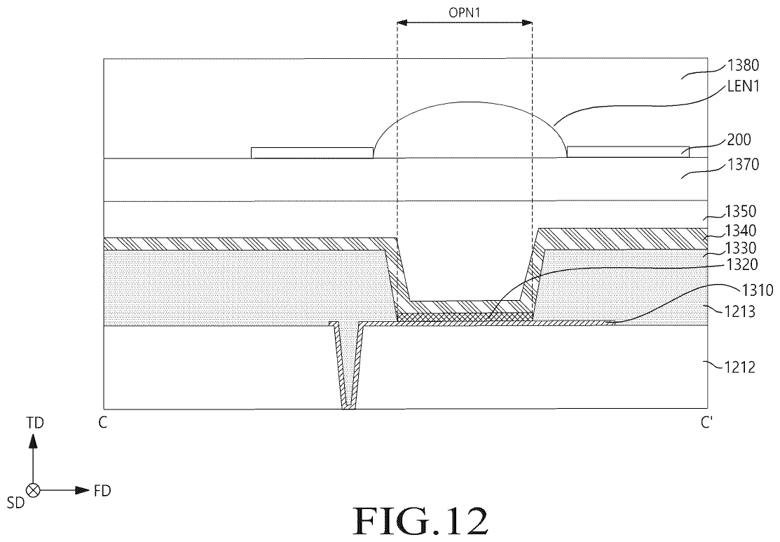

FIG. 12 is a cross-sectional view taken along the line C-C′ of FIG. 9A according to one embodiment.

A first insulating layer (not shown), a second insulating layer 1212, a third insulating layer 1213, a first electrode layer 1310, a light emitting layer 1320, a bank layer 1330, a second electrode layer 1340, an encapsulation layer 1350, a touch buffer layer (not shown), a touch interlayer insulating layer 1370, a planarization layer 1380, a first lens part LEN1 and a touch sensor 210 of FIG. 12 may be substantially the same as the first insulating layer 1211, the second insulating layer 1212, the third insulating layer 1213, the first electrode layer 1310, the light emitting layer 1320, the bank layer 1330, the second electrode layer 1340, the encapsulation layer 1350, the touch buffer layer 1360, the touch interlayer insulating layer 1370, the planarization layer 1380, the first lens part LEN1 and the touch sensor 210 described with reference to FIG. 10.

Referring to FIG. 12, in FIG. 9A, in the case where the concave portion 410 disposed in the first subpixel does not include two points at which an imaginary straight line passing through the center point of the opening area OPN1 in the first subpixel and parallel to the first direction FD meets the boundaries of the opening area OPN1 in the first subpixel, as a viewing angle in the first direction FD is reduced by the first lens part LEN1, the wide viewing angle mode desired by the user may be realized.

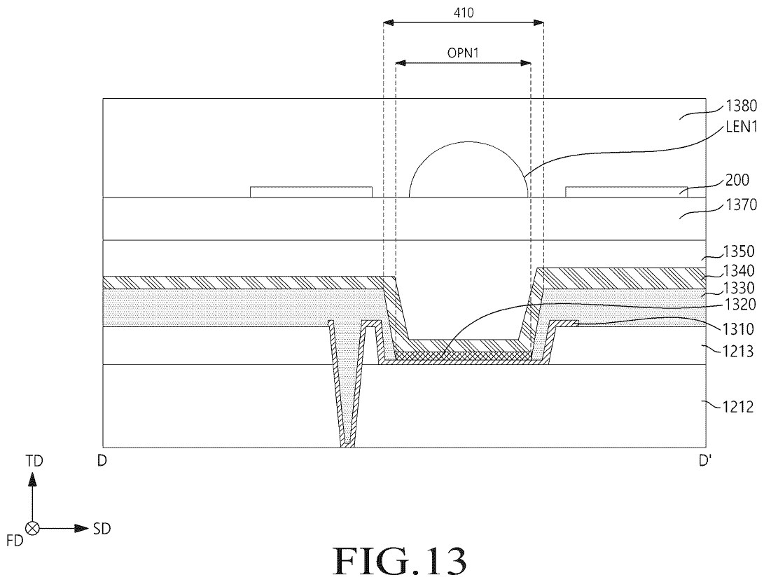

FIG. 13 is a cross-sectional view taken along the line D-D′ of FIG. 9C according to one embodiment.

A first insulating layer (not shown), a second insulating layer 1212, a third insulating layer 1213, a first electrode layer 1310, a light emitting layer 1320, a bank layer 1330, a second electrode layer 1340, an encapsulation layer 1350, a touch buffer layer (not shown), a touch interlayer insulating layer 1370, a planarization layer 1380, a first lens part LEN1 and a touch sensor 210 of FIG. 13 may be substantially the same as the first insulating layer 1211, the second insulating layer 1212, the third insulating layer 1213, the first electrode layer 1310, the light emitting layer 1320, the bank layer 1330, the second electrode layer 1340, the encapsulation layer 1350, the touch buffer layer 1360, the touch interlayer insulating layer 1370, the planarization layer 1380, the first lens part LEN1 and the touch sensor 210 described with reference to FIG. 10.

Referring to FIG. 13, as illustrated in FIG. 9C, the first lens part LEN1 may cover the opening area OPN1 in the first subpixel, and may cover a portion of the concave portion 410 disposed in the first subpixel.

When the first lens part LEN1 is designed as illustrated in FIG. 9C, the first lens part LEN1 extracts light emitted through the opening area OPN1 in the first subpixel, and light emitted by the first concave portion 410 is not extracted by the first lens part LEN1.

Accordingly, since light emitted by the first concave portion 410 is not extracted by the first lens part LEN1, luminance efficiency decreases, but a viewing angle in the second direction SD increases, whereby the enhanced wide viewing angle mode may be realized.

Brief description of the embodiments of the present disclosure described above is as follows.

A display device according to embodiments of the present disclosure may include an insulating layer located on a substrate, and including a plurality of concave portions which are located in a plurality of subpixels, respectively, an area of a first concave portion disposed in a first subpixel among the plurality of subpixels being larger than an area of a second concave portion disposed in a second subpixel among the plurality of subpixels; and a plurality of lens parts located on the insulating layer, and including a first lens part corresponding to the first concave portion and a second lens part corresponding to the second concave portion.

The display device according to the embodiments of the present disclosure may further include an encapsulation layer located on the insulating layer, and disposed below the plurality of lens parts; and a planarization layer located on the plurality of lens parts, and covering at least a portion of a side surface of the encapsulation layer.

In the display device according to the embodiments of the present disclosure, a refractive index of the planarization layer may be smaller than a refractive index of the plurality of lens parts.

The display device according to the embodiments of the present disclosure may further include at least one upper dam located outside the planarization layer.

The display device according to the embodiments of the present disclosure may further include at least one lower dam located outside the encapsulation layer, and located between the at least one upper dam and an active area.

The display device according to the embodiments of the present disclosure may further include a plurality of touch sensors located at a layer where the plurality of lens parts are disposed, on the encapsulation layer, and disposed in at least a portion of an area other than an area where the plurality of lens parts are disposed.

The display device according to the embodiments of the present disclosure may further include a color filter located between the encapsulation layer and a layer where the plurality of touch sensors are disposed.

The display device according to the embodiments of the present disclosure may further include a plurality of black matrices located at a layer where the color filter is disposed, on the encapsulation layer, and disposed in at least a portion of an area other than an area where the color filter is disposed.

The display device according to the embodiments of the present disclosure may further include a plurality of connection patterns located at the layer where the color filter and the black matrices are disposed, and electrically connected to at least one of the plurality of touch sensors.

A display device according to embodiments of the present disclosure may include an insulating layer located on a substrate, and including a plurality of concave portions which are disposed in a plurality of subpixels and each of which includes a flat portion and a sloped portion surrounding the flat portion in each subpixel; a bank layer located on the insulating layer and including an opening area in each subpixel, the opening area being surrounded by the sloped portion, wherein an opening area in a first subpixel among the plurality of subpixels is wider than an opening area in a second subpixel among the plurality of subpixels, and wherein a concave portion disposed in the first subpixel surrounds a portion of the opening area in the first subpixel, and a concave portion disposed in the second subpixel surrounds the opening area in the second subpixel; and a plurality of lens parts located on the insulating layer, and including a first lens part corresponding to the concave portion disposed in the first subpixel and a second lens part corresponding to the concave portion disposed in the second subpixel.

In the display device according to the embodiments of the present disclosure, when viewed on a plane defined by a first direction and a second direction perpendicular to the first direction, a distance between two points at which an imaginary straight line passing through a center point of the opening area in the first subpixel and parallel to the second direction meets boundaries of the opening area in the first subpixel may be longer than a distance between two points at which an imaginary straight line passing through the center point of the opening area in the first subpixel and parallel to the first direction meets boundaries of the opening area in the first subpixel, and the concave portion disposed in the first subpixel may include the two points at which the imaginary straight line passing through the center point of the opening area in the first subpixel and parallel to the second direction meets the boundaries of the opening area in the first subpixel.

In the display device according to the embodiments of the present disclosure, when viewed on a plane defined by a first direction and a second direction perpendicular to the first direction, a distance between two points at which an imaginary straight line passing through a center point of the opening area in the second subpixel and parallel to the first direction meets boundaries of the opening area in the second subpixel may be the same as a distance between two points at which an imaginary straight line passing through the center point of the opening area in the second subpixel and parallel to the second direction meets boundaries of the opening area in the second subpixel.

The display device according to the embodiments of the present disclosure may further include a plurality of touch sensors located on the insulating layer, and disposed in at least a portion of an area other than an area where the plurality of lens parts are disposed.

The display device according to the embodiments of the present disclosure may further include a plurality of black matrices located on the insulating layer, and disposed in at least a portion of an area other than the area where the plurality of lens parts are disposed.

The display device according to the embodiments of the present disclosure may further include a plurality of connection patterns electrically connected to at least one of the plurality of touch sensors.

In the display device according to the embodiments of the present disclosure, the first lens part may cover the opening area in the first subpixel, and may cover the concave portion disposed in the first subpixel.

In the display device according to the embodiments of the present disclosure, the first lens part may cover the opening area in the first subpixel, and may cover only a portion of the concave portion disposed in the first subpixel.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A semiconductor device comprising:
a substrate including a plurality of subpixels;
an insulating layer on the substrate and including a plurality of concave portions that extend through a thickness of the insulating layer, the plurality of concave portions including a first concave portion in a first subpixel from the plurality of subpixels and a second concave portion in a second subpixel from the plurality of subpixels;
a bank layer on the insulating layer and including a plurality of openings, the plurality of openings including a first opening that overlaps the first concave portion and a second opening that overlaps the second concave portion; and
a plurality of lens parts over the insulating layer and the bank layer, the plurality of lens parts including a first lens part that overlaps the first concave portion and the first opening and a second lens part that overlaps the second concave portion and the second opening,
wherein an area of the first concave portion is larger than an area of the second concave portion.

2. The semiconductor device of claim 1, further comprising:
an encapsulation layer between the bank layer and the plurality of lens parts; and
a planarization layer on the plurality of lens parts, the planarization layer covering at least a portion of a side surface of the encapsulation layer.

3. The semiconductor device of claim 2, wherein a refractive index of the planarization layer is less than a refractive index of the plurality of lens parts.

4. The semiconductor device of claim 2, further comprising:
at least one upper dam, wherein an end of the planarization layer contacts the at least one upper dam.

5. The semiconductor device of claim 4, further comprising:
at least one lower dam that is closer to the substrate than the at least one upper dam, wherein the at least one lower dam is between the at least one upper dam and the bank layer in a cross-section view of the semiconductor device.

6. The semiconductor device of claim 2, further comprising:
a plurality of touch sensors on a same layer as the plurality of lens parts.

7. The semiconductor device of claim 6, further comprising:
a color filter between the encapsulation layer and the same layer where the plurality of touch sensors and the plurality of lens parts are disposed.

8. The semiconductor device of claim 7, further comprising:
a plurality of black matrices on a same layer as the color filter, the plurality of black matrices non-overlapping with the plurality of lens parts.

9. The semiconductor device of claim 8, further comprising:
a plurality of connection patterns on the same layer as the color filter and the plurality of black matrices, the plurality of connection patterns electrically connected to at least one of the plurality of touch sensors.

10. A semiconductor device comprising:
a substrate;
an insulating layer on the substrate and including a plurality of concave portions that extend through a thickness of the insulating layer and are in a plurality of subpixels, each of the plurality of concave portions including a flat portion and a sloped portion that extends from the flat portion and surrounds the flat portion;
a bank layer on the insulating layer and including a plurality of opening areas that are each in a corresponding subpixel from the plurality of subpixels, the plurality of opening areas including a first opening area in a first subpixel from the plurality of subpixels that is surrounded by a first concave portion from the plurality of concave portions and a second opening area in a second subpixel from the plurality of subpixels that is surrounded by a second concave portion from the plurality of concave portions; and
a plurality of lens parts over the bank layer and the insulating layer, the plurality of lens parts including a first lens part that overlaps the first opening area and the first concave portion and a second lens part that overlaps the second opening area and the second concave portion,
wherein the first opening area is wider than the second opening area.

11. The semiconductor device of claim 10, wherein in a plane view of the semiconductor device defined by a first direction and a second direction that is perpendicular to the first direction, a first distance between a first pair of points at which a first imaginary straight line passes through a center point of the first opening area in the first subpixel and parallel to the second direction meets boundaries of the first opening area in the first subpixel is longer than a second distance between a second pair of points at which a second imaginary straight line passing through the center point of the first opening area in the first subpixel and is parallel to the first direction meets boundaries of the first opening area in the first subpixel, and
the first concave portion in the first subpixel surrounds the first pair of points at which the first imaginary straight line passing through the center point of the first opening area in the first subpixel and parallel to the second direction meets the boundaries of the first opening area in the first subpixel.

12. The semiconductor device of claim 10, wherein in a plane view of the semiconductor device defined by a first direction and a second direction that is perpendicular to the first direction, a first distance between a first pair of points at which a first imaginary straight line passes through a center point of the second opening area in the second subpixel and parallel to the first direction meets boundaries of the second opening area in the second subpixel is a same as a second distance between a second pair of points at which a second imaginary straight line passes through the center point of the second opening area in the second subpixel and parallel to the second direction meets boundaries of the second opening area in the second subpixel.

13. The semiconductor device of claim 10, further comprising:
a plurality of touch sensors that are non-overlapping with the plurality of lens parts in a plane view of the semiconductor device.

14. The semiconductor device of claim 13, further comprising:
a plurality of black matrices that overlap the plurality of touch sensors.

15. The semiconductor device of claim 14, further comprising:
a plurality of connection patterns electrically connected to at least one of the plurality of touch sensors.

16. The semiconductor device of claim 10, wherein the first lens part has a width that is wider than a width of the first opening area in the first subpixel, and is wider than a width of the first concave portion in the first subpixel.

17. The semiconductor device of claim 10, wherein the first lens part has a width that is less than a width of the first opening area in the first subpixel, and is less than a width of the first concave portion in the first subpixel.

18. A display device comprising:
a substrate;
a plurality of transistors on the substrate, the plurality of transistors including a first transistor;
a first insulating layer on the plurality of transistors, the first insulating layer including a first concave portion through a thickness of the first insulating layer;
a first light emitting element that is in the first concave portion, the first light emitting element connected to the first transistor and including a first electrode layer in the first concave portion, a first light emitting layer on the first electrode layer in the first concave portion, and a first portion of a second electrode layer on the first light emitting layer in the first concave portion;
a bank layer on the first insulating layer, the bank layer including a first opening that extends into the first concave portion; and
a plurality of lens parts over the first insulating layer, the plurality of lens parts including a first lens part that overlaps the first concave portion and the first opening.

19. The display device of claim 18, further comprising:
a second insulating layer that is between the first insulating layer and the plurality of transistors,
wherein the first concave portion includes a first flat portion that corresponds to a first portion of an upper surface of the second insulating layer that is exposed by the first concave portion and first inclined sides of the first insulating layer that extend from the first flat portion and surrounds the first flat portion.

20. The display device of claim 18, wherein the plurality of transistors further comprise a second transistor, the first insulating layer further comprises a second concave portion through the thickness of the first insulating layer, the bank layer further comprises a second opening that extends into the second concave portion, and the plurality of lens parts further comprises a second lens part overlapping the second concave portion and the second opening,
wherein the display device further comprises:
a second light emitting element that is in the second concave portion, the second light emitting element connected to the second transistor and including a second electrode layer in the second concave portion, a second light emitting layer on the second electrode layer in the second concave portion, and a second portion of the second electrode layer on the second light emitting layer in the second concave portion.

21. The display device of claim 20, wherein an area of the first concave portion is larger than an area of the second concave portion.

22. The display device of claim 20, wherein a width of the first opening is less than a width of the second opening.

23. The display device of claim 18, further comprising:
a color filter between the first lens part and the first light emitting element.

24. The display device of claim 23, further comprising:
a plurality of touch sensors on a same layer as the plurality of lens parts; and
a plurality of black matrices on a same layer as the color filter,
wherein the plurality of black matrices overlap the plurality of touch sensors without overlapping the plurality of lens parts.

25. The display device of claim 18, wherein an end of the first light emitting layer is between the bank layer and the first electrode layer.

26. The display device of claim 18, wherein the first lens part has a width that is wider than a width of the first opening and is wider than a width of the first concave portion.

27. The display device of claim 18, wherein the first lens part has a width that is less than a width of the first opening and is less than a width of the first concave portion.
